(19) United States
(12) Patent Application Publication
(10) Pub. No.: US 2009/0079333 A1
(43) Pub. Date: Mar. 26, 2009

(54) LIGHT-EMITTING DEVICE

(75) Inventor: Hongmo Koo, Gumi-city (KR)

Correspondence Address: KED & ASSOCIATES, LLP, P.O. Box 221200, Chantilly, VA, 20153-1200, US

(73) Assignee: LG Electronics Inc.

(21) Appl. No.: 11/949,999

(22) Filed: Dec. 4, 2007

(30) Foreign Application Priority Data
Sep. 21, 2007 (KR) 10-2007-0097019

(51) Int. Cl. H01L 27/28

(52) U.S. Cl. 313/504

(57) ABSTRACT

A light emitting device according to an embodiment of this document comprises a substrate comprising a thin film transistor, an insulating film disposed over the substrate and having a via hole through which the thin film transistor is exposed, a first electrode disposed over the insulating film and connected to the thin film transistor through the via hole, a light-emitting layer disposed on the first electrode, and a second electrode disposed on the light-emitting layer. A thickness of the first electrode may be substantially 2 to 3.3 times greater than that of the light-emitting layer, and a thickness of the second electrode may be substantially 2 to 6.6 times greater than that of the light-emitting layer.

This application claims the benefit of Korean Patent Application No. 10-2007-0097019 filed in Korea on 21 Sep., 2007, which is hereby incorporated by reference.

### BACKGROUND

1. Field

One or more embodiments described herein related to a display device.

2. Background

The importance of flat panel displays has increased with consumer demand for multimedia products and services. One type of flat panel display known as an organic light emitting device (OLED) has high response speed, low power consumption, and a wide viewing angle. In spite of these advantages, OLEDs continue to demonstrate low emission efficiency which makes then unreliable.

### BRIEF DESCRIPTION OF THE DRAWINGS

FIGS. 1a to 1c are cross-sectional views of one embodiment of a light emitting device.

FIGS. 2a to 2d are cross-sectional views of another embodiment of a light emitting device.

FIGS. 3A to 3C illustrate various implementations of a color image display method in an organic light emitting device according to an exemplary embodiment.

### DETAILED DESCRIPTION

One type of light emitting device emits light when excitons, created when electrons and holes combine in an emitting layer, drop from an excited state to a ground state. The electrons and holes are supplied from electron injection and holes injection electrodes respectively. Generally, a light-emitting device of this type is formed from a single layer or a plurality of organic layers (or inorganic layers) stacked between an anode electrode (the hole injection electrode) and a cathode electrode (the electron injection electrode). The organic layer or emits light in response to a voltage applied to the electrodes.

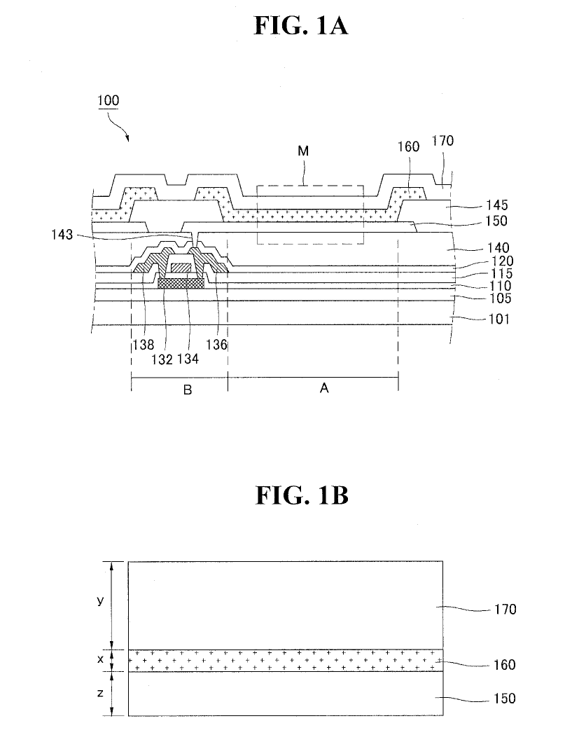

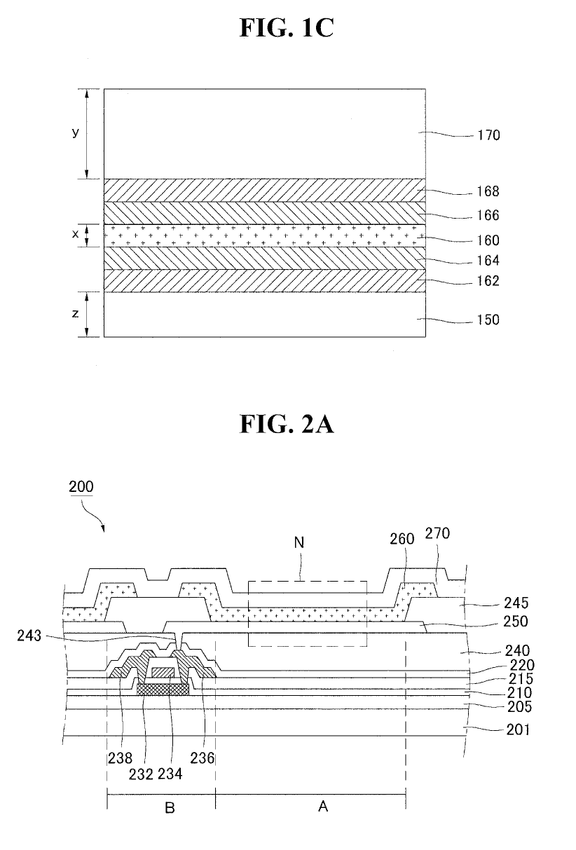

FIGS. 1a to 1c are cross-sectional views of one embodiment of a light emitting device that achieves improved emission efficiency, low power consumption, and/or increased process efficiency. This device 100 includes a substrate 101, a buffer layer 105, a thin film transistor, first to fifth insulating films, a first electrode 150, a light-emitting layer 160, a second electrode 170.

The substrate 101 may be formed from a transparent glass or plastic material. The buffer layer 105 is formed on the substrate and may serve to prevent impurities from entering the device from the substrate during a subsequent manufacturing process of the light emitting device. The buffer layer may be formed from a silicon nitride film (SiNₓ), a silicon oxide film (SiO₂), or a silicon oxynitride film (SiOₓNₓ).

The thin film transistor may be formed from a gate electrode 134, a source electrode 138, a drain electrode 136, and a semiconductor layer 132. In accordance with one embodiment, the thin film transistor has a coplanar structure; that is, the thin film transistor has a top-gate structure in which gate electrode 134 is disposed over the semiconductor layer 132. A different structure may be used in alternative embodiments.

The semiconductor layer 132 may be formed on the buffer layer and may form a channel in the thin film transistor. The semiconductor layer, for example, may be made of a crystalline, poly-crystalline, or amorphous material. One non-limiting example is silicon (Si).

A first insulating film 110, which may serve as a gate insulating film, is formed on the buffer layer on which the semiconductor layer is formed. The first insulating film may be made of SiNₓ or SiO₂ but is not limited thereto. The gate insulating film functions to insulate the gate electrode from source electrode 138 and drain electrode 136.

The gate electrode 134 may be formed at a location corresponding to semiconductor layer 132 on the first insulating film. The gate electrode may turn on/off the thin film transistor in response to a data voltage supplied from a data line (not shown).

A second insulating film 115, which may serve as an interlayer insulating film, is formed on first insulating film 110 having gate electrode 134 formed thereon. The second insulating film may be made of a SiNₓ or SiO₂ material, but is not limited thereto.

Contact holes may be formed in first insulating film 110 and second insulating film 115 in order to form source electrode 138 and drain electrode 136 connected to semiconductor layer 132. The source and drain electrodes are connected to the semiconductor layer through the contact holes, and may be projected upwardly from second insulating film 115.

The gate electrode 134, source electrode 138, and drain electrode 136 may have a stack structure and may be made of at least one layer of chrome (Cr), aluminum (Al), molybdenum (Mo), silver (Ag), copper (Cu), titanium (Ti), tantalum (Ta) or an alloy thereof.

A third insulating film 120, which may serve as an inorganic passivation film, may be formed over the thin film transistor and second insulating film. The inorganic passivation film is preferably formed to provide a passivation effect of the semiconductor layer 132 and an external light-shielding effect.

A fourth insulating film 140, which may serve as a planarization film, may be formed over the substrate over which the third insulating film 120 is formed. A via hole through which part of the thin film transistor is exposed may be formed in the fourth insulating film. More specifically, a via hole 143 may be formed in third insulating film 120 and fourth insulating film 140, and part of drain electrode 136 may extend through this hole. The fourth insulating film may be made of benzocyclobutene, polyimide, or acrylic resin, but is not limited thereto.

The first electrode 150 may be formed on the fourth insulating film 140, and may be electrically connected to drain electrode 136 of the thin film transistor through the via hole 143 formed in the fourth insulating film 140 and the third insulating film 120. The first electrode may be an anode electrode, may be supplied with a voltage from the thin film transistor, and may supply holes to the light-emitting layer 160.

A fifth insulating film 145, which may serve as a pixel definition film, is formed over fourth insulating film 140 and first electrode 150. An opening, through which part of the first electrode 150 is exposed to define a light-emitting region A, may be formed in the fifth insulating film. The fifth insulating film may be made of benzocyclobutene, polyimide, or acrylic resin, but is not limited thereto.

The light-emitting layer 160 is preferably formed on the first electrode and may be supplied with holes from first electrode 150.

The second electrode 170 may be disposed in opposing relation to the first electrode, with light-emitting layer therebetween. The second electrode may serve as a cathode electrode and may be made of aluminum (Al), magnesium (Mg), silver (Ag), calcium (Ca) or an alloy thereof, but is not limited thereto.

The light-emitting layer 160 is supplied with holes and electrons from the first electrode and second electrode, which when combined generates excitons. When the excitons return to a stable or base state, the light-emitting layer emits light in a forward direction to thereby display light from a sub-pixel that helps to form in an image.

FIG. 1b is an enlarged view of a portion “M” in FIG. 1a, and FIG. 1c is a view illustrating not only the light-emitting layer, but also other function layers which may be added between the first and second electrodes.

Referring to FIGS. 1b to 1c, light emitting device 100 shown in this drawing has a bottom-emission structure. In this structure, a ratio of a thickness of each electrode and a thickness of light-emitting layer 160 has an organic relationship in terms of emission efficiency, power consumption, and/or process efficiency of devices.

Furthermore, the first electrode 150, light-emitting layer 160, and second electrode 170 are sequentially formed and have a predetermined thickness (width). According to one embodiment, the thickness Z of the first electrode may be substantially 2 to 3.3 times greater than a thickness X of the light-emitting layer 160.

In a bottom-emission structure, when the thickness of first electrode 150 is less than twice that of the light-emitting layer, electrical characteristics are degraded and power consumption is increased. Further, the first electrode is formed using a transparent material such as ITO or IZO. This material has a rough surface and is not uniform when deposited thinly on the fourth insulating film 140. Accordingly, only part of the first electrode may be degraded and, therefore, dark spots may be generated around the degraded portion. Moreover, there may be a problem in thickness control upon etching.

When the thickness of the first electrode is 3.3 times greater than that of the light-emitting layer, transmittance of light decreases and a process problem such as increased etching time occurs.

A thickness Y of second electrode 170 may be substantially 2 to 6.7 times greater than the thickness X of light-emitting layer 160. When the thickness of the second electrode is less than twice that of the light-emitting layer, electrical characteristics may be degraded and power consumption may be increased.

When the thickness of the second electrode is 6.7 times greater than that of the light-emitting layer, the light-emitting layer may be damaged due to heat and stress, which are generated in the process of depositing the second electrode on the light-emitting layer. Furthermore, since the ratio of holes supplied from the first electrode does not coincide with the ratio of electrons supplied from the second electrode, the balance of charges is not maintained, thereby making formation of excitons irregular.

The light emitting device 100 according to the present embodiment may have good emission efficiency and may generate uniform light from a sub pixel when first electrode 150, light-emitting layer 160, and second electrode 170 have the above numerical values. The light emitting device may also have lower power consumption by contrast with emission efficiency, and is efficient in terms of a process such as etching.

In this case, at least one of a hole injection layer 162 and a hole transfer layer 164 may be sequentially formed over the first electrode between first electrode 150 and light-emitting layer 160. As a result, holes can be smoothly transported from the first electrode 150 to the light-emitting layer.

Also, at least one of an electron transfer layer 166 and an electron injection layer 168 may be formed sequentially over the light-emitting layer 160 between the light-emitting layer and the second electrode. As a result, electrons can be smoothly transported from the second electrode 170 to the light-emitting layer 160.

At least one of the light-emitting layer 160, hole injection layer 162, hole transfer layer 164, electron transper layer 166, or electron injection layer 168 may comprise an organic material or an inorganic material, or both.

The electron injection layer 168 below the second electrode may be formed from lithium fluoride (LiF), to thereby form a strong dipole. Lithium fluoride (LiF) may be preferable in some applications because it has a strong ion bond characteristic. In general, bonds between chemical elements can be largely classified into covalent bonds and ion bonds. They can also be classified according to the absolute value of a difference in the electronegativity of respective chemical elements. Generally, when the absolute value of a difference in the electronegativity of respective chemical element is 1.67 or higher, it can be said that bonds between the chemical elements are ion bonds.

In lithium fluoride (LiF), the electronegativity of lithium is 3.98 and the electronegativity of fluorine is 0.98. Thus, the absolute value of a difference in the electronegativity of lithium and fluorine becomes 3. The result shows that lithium fluoride (LiF) has very strong ion bonds. Strong bonds of ion bonds form a dipole within the bonds. In other words, lithium fluoride (LiF) is a material having strong ion bonds to form a dipole, and a distance between the atoms of the two chemical elements is very close.

Lithium fluoride (LiF) forms a strong dipole and thus increases the injection of electrons into the light-emitting layer 160. Accordingly, emission efficiency can be improved and a driving voltage can be lowered. Furthermore, a lithium complex (Liq) has bonding force weaker than that of lithium fluoride (LiF), but is used as the material of the electron injection layer. Accordingly, it can increase electron injection and improve emission efficiency.

According to one embodiment, the hole injection layer 162 or electron injection layer 168, which may be formed using organic material, may further comprise an inorganic material. The inorganic material may be a metal compound including an alkali metal or alkali earth metal such as but not limited to LiF, NaF, KF, RbF, CsF, FrF, BeF2, MgF2, CaF2, SrF2, BaF2, or RaF2.

Generally, in a light emitting device, for example, without strategic placement of an inorganic material, hole mobility may be 10 times faster than the electron mobility. Thus, the amount of holes injected into a light-emitting layer may differ from the amount of electrons injected into the light-emitting layer. Accordingly, emission efficiency may be degraded.

According to the present embodiment, providing the aforementioned inorganic material serves to lower the highest level of a valence band of the hole injection layer 162 formed using the organic material and the lowest level of a conduction band of the electron injection layer 168 formed using the organic material.

That is, providing inorganic material within hole injection layer 162 or electron injection layer 168 may function to lower the mobility of holes injected from the first electrode to the light-emitting layer, or may increase the mobility of electrons injected from the second electrode to the light-emitting layer. Accordingly, as the balance of the holes and the electrons is maintained, emission efficiency can be improved.

Moreover, in accordance with at least one embodiment, a fluorescent material or a phosphor material may be used as the material of the light-emitting layer.

For example, a red light-emitting layer may be formed from a host material comprising CBP (carbazole biphenyl) or mCP(1,3-bis(carbazol-9-yl)), and/or may be formed using a phosphor material comprising a dopant that includes any one or more selected from the group comprising PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), or PtOEP(octaethylporphyrin platinum). Further, an iridium-based transfer metal compound may be used such as iridium(III)(2-(3-methylphenyl)-6-methylquinolinato-N,C2′)(2,4-pentanedionate-O,O), or platinum porphyrin. Alternatively, the red light-emitting layer may be comprised of a fluorescent material comprising PBD:Eu(DBM)3(Phen) or perylene.

In the case where the emitting layer emits red light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.0 to 6.0 eV, and a lowest unoccupied molecular orbital of the dopant material may range from 2.4 to 3.5 eV.

A blue light-emitting layer comprises a host material comprising CBP or mCP, and may be formed using a phosphor material comprising a dopant material comprising (4,6-F2ppy)2Irpic. An iridium-based transfer metal compounds may also be used such as (3,4-CN)3Ir, (3,4-CN)2Ir (picolinic acid), (3,4-CN)2Ir(N3), (3,4-CN)2Ir(N4), or (2,4-CN)3Ir. Alternatively, the blue light-emitting layer may be formed from a fluorescent material comprising any one selected from a group comprising spiro-DPVBi, spiro-6P, distylbenzene (DSB), distrylarylene (DSA), or PFO-based polymers, or a PPV-based polymer.

In the case where the emitting layer emits blue light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.5 to 6.0 eV, and a lowest unoccupied molecular orbital of the dopant material may range from 2.0 to 3.5 eV.

A green light-emitting layer comprises a host material comprising CBP or mCP, and may be formed from a phosphor material comprising a dopant material comprising Ir(ppy)3(fac tris(2-phenylpyridine)iridium). Tris(2-:pyridine)Ir(III) may also be used. Alternatively, the green light-emitting layer may be formed using a fluorescent material comprising Alq3(tris(8-hydroxyquinolino)aluminum).

In the case where the emitting layer emits green light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.5 to 6.0 eV, and a lowest unoccupied molecular orbital of the dopant material may range from 2.0 to 3.5 eV.

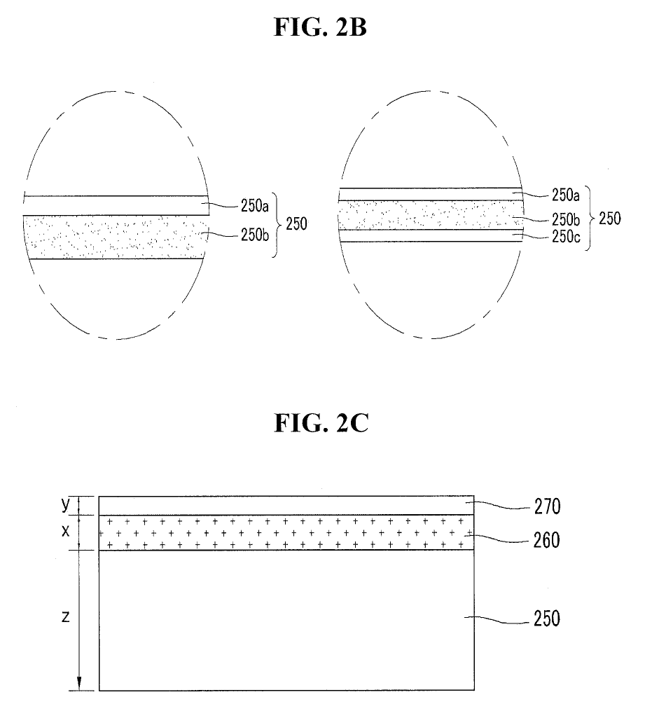

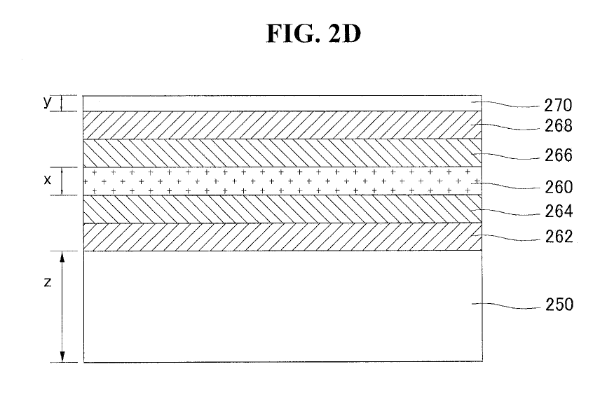

FIGS. 2a to 2d show a light emitting device 200 in accordance with another embodiment, which device 200 has a similar structure as that of light emitting device 100 described with reference to FIG. 1a. However, light emitting device 200 differs from light emitting device 100 in the stack structure of a first electrode 250 and a ratio of electrode thickness and light-emitting layer 260 since it has a top-emission structure.

FIG. 2b is an enlarged view of first electrode 250 of FIG. 2a. As shown, first electrode 250 is formed on fourth insulating film 240 and may have a two-layer structure comprising a reflection electrode 250b connected to the thin film transistor through a via hole 243, and a first transparent electrode 250a formed on the reflection electrode. The reflection electrode can be electrically connected to drain electrode 236 of the thin film transistor, and the first transparent electrode can be electrically connected to the reflection electrode.

In a top-emission structure, the reflection electrode may be disposed on a lower side of the first electrode and may function to reflect light, generated from light-emitting layer 260, to the second electrode 270. The reflection electrode may be made of silver (Ag), aluminum (Al), or nickel (Ni), which have a good reflectance, but it is not limited thereto.

Alternatively, the first electrode is formed on fourth insulating film 240 and may have a three-layer structure comprising a second transparent electrode 250c connected to drain electrode 236 of the thin film transistor through via hole 243, and a reflection electrode 250b and a first transparent electrode 250a formed over the second transparent electrode 250c.

If the first electrode further comprises second transparent electrode 250c formed below reflection electrode 250b, a contact ability can be improved when connected to the thin film transistor. The first transparent electrode 250a and the second transparent electrode 250c may be formed using either ITO or IZO, but are not limited thereto.

FIG. 2c is an enlarged view of a portion “N” in FIG. 2a, and FIG. 2d is a view showing not only the light-emitting layer but also other function layers which are added between the first and second electrodes.

In this light emitting device 200, the ratio of a thickness of each electrode and a thickness of light-emitting layer 260 has an organic relationship in terms of emission efficiency, power consumption, and/or process efficiency.

Referring to FIGS. 2c to 2d, the first electrode 250, the light-emitting layer 260, and the second electrode 270 are formed sequentially and have a predetermined thickness (width). According to one embodiment, thickness Y of the second electrode 270 may be substantially 0.2 to 0.33 times greater than a thickness X of the light-emitting layer 260.

The top-emission structure may have characteristics opposite to those of the bottom-emission structure. For example, when the thickness of the second electrode 270 is 0.2 times less than that of the light-emitting layer, electrical conductivity is lowered and, therefore, power consumption may increase or the leakage current may occur. It may also be difficult to control thickness upon etching.

When the thickness of the second electrode 270 is 0.33 times greater than that of the light-emitting layer, transmittance may decrease. In addition, stress due to heat may be large and the second electrode may have a tendency to bend to one side due to the stress, when the second electrode is thickly deposited on an opposite side of the substrate.

According to one embodiment, the thickness Z of the first electrode 250 may be substantially 4.2 to 7.7 times greater than the thickness X of the light-emitting layer 260.

When the thickness of the first electrode 250 is less than 4.2 times that of the light-emitting layer, electrical characteristics may be degraded, resulting in increased power consumption. When the thickness of the first electrode is greater than 7.7 times that of the light-emitting layer, the ratio of electrons supplied from the second electrode does not coincide with the ratio of holes supplied from the first electrode, the balance of charges is not maintained, and therefore the formation of excitons is irregular.

On the other hand, when the first electrode, light-emitting layer, and second electrode are formed according to the aforementioned numerical ranges, a light-emitting device may be formed to have good emission efficiency and improved uniformity of light. The light emitting device may also have lower power consumption by contrast with emission efficiency, and is efficient in terms of a process such as etching.

To achieve these improvements, at least one of hole injection layer 262 or a hole transfer layer 264 may be sequentially formed over the first electrode 250 between the first electrode and light-emitting layer, to thereby cause holes to be smoothly transported from the first electrode to the light-emitting layer.

Also, or alternatively, at least one of an electron transfer layer 266 or an electron injection layer 268 may be sequentially formed over the light-emitting layer 260 between the light-emitting layer and the second electrode, to allow electrons to be smoothly transported from the second electrode 270 to the light-emitting layer 260.

At least one of the light-emitting layer 260, hole injection layer 262, hole transfer layer 264, electron transper layer 266, or the electron injection layer 268 may be formed using an organic material or an inorganic material, or both.

The electron injection layer 268 formed below the second electrode 270 may be made of lithium fluoride (LiF) to form a strong dipole. Lithium fluoride (LiF) forms a strong dipole and thus increases the injection of electrons into the light-emitting layer 260. Accordingly, emission efficiency can be improved and a driving voltage can be lowered.

The hole injection layer 262 or the electron injection layer 268, which is formed using the organic material, may further comprise an inorganic material. The inorganic material may further comprise a metal compound including an alkali metal or an alkali earth metal such as but not limited to any one selected from a group comprising LiF, NaF, KF, RbF, CsF, FrF, BeF2, MgF2, CaF2, SrF2, BaF2, or RaF2.

Because hole mobility may be generally 10 times faster than electron mobility, the amount of holes injected into a light-emitting layer may be different from the amount of electrons injected into the light-emitting layer. Accordingly, emission efficiency may be degraded.

However, in order to overcome this effect, one or more embodiments described herein include the aforementioned inorganic material, which functions to lower the highest level valence band of the hole injection layer 262 and the lowest level of conduction band of the electron injection layer 268.

In this case, the inorganic material within the hole injection layer 262 or the electron injection layer 268 may function to lower the mobility of holes injected from the first electrode to the light-emitting layer 260 or increase the mobility of electrons injected from the second electrode to the light-emitting layer 260. Accordingly, as the balance of the holes and the electrons is maintained, emission efficiency can be improved.

Thus, a light-emitting device may be formed with improved emission efficiency, low power consumption, and increased process efficiency.

According to one aspect, a light emitting device according to an embodiment of this document comprises a substrate comprising a thin film transistor, an insulating film disposed over the substrate and having a via hole through which the thin film transistor is exposed, a first electrode disposed over the insulating film and connected to the thin film transistor through the via hole, a light-emitting layer disposed on the first electrode, and a second electrode disposed on the light-emitting layer. A thickness of the first electrode may be substantially 2 to 3.3 times greater than that of the light-emitting layer, and a thickness of the second electrode may be substantially 2 to 6.7 times greater than that of the light-emitting layer.

According to another aspect, a light emitting device according to an embodiment of this document comprises a substrate comprising a thin film transistor, an insulating film disposed over the substrate and having a via hole through which the thin film transistor is exposed, a first electrode disposed over the insulating film and connected to the thin film transistor through the via hole, a light-emitting layer disposed on the first electrode, and a second electrode disposed on the light-emitting layer. A thickness of the first electrode may be substantially 4.2 to 7.7 times greater than that of the light-emitting layer, and a thickness of the second electrode may be substantially 0.2 to 0.33 times greater than that of the light-emitting layer.

In accordance with any of the embodiments described herein, in a case where the emitting layer emits red light, the emitting layer may include a host material including carbazole biphenyl (CBP) or 1,3-bis(carbazol-9-yl (mCP), and may be formed of a phosphorescence material including a dopant material including PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), or PtOEP(octaethylporphyrin platinum) or a fluorescence material including PBD:Eu(DBM)3(Phen) or Perylene.

In the case where the emitting layer emits red light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.0 to 6.0 eV, and a lowest unoccupied molecular orbital of the dopant material may range from 2.4 to 3.5 eV.

In the case where the emitting layer emits green light, the emitting layer includes a host material including CBP or mCP, and may be formed of a phosphorescence material including a dopant material including Ir(ppy)3(fac tris(2-phenylpyridine)iridium) or a fluorescence material including Alq3(tris(8-hydroxyquinolino)aluminum).

In the case where the emitting layer emits green light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.5 to 6.0 eV, and a lowest unoccupied molecular orbital of the dopant material may range from 2.0 to 3.5 eV.

In the case where the emitting layer emits blue light, the emitting layer includes a host material including CBP or mCP, and may be formed of a phosphorescence material including a dopant material including (4,6-F2ppy)2Irpic or a fluorescence material including spiro-DPVBi, spiro-6P, distyryl-benzene (DSB), distyryl-arylene (DSA), PFO-based polymers, PPV-based polymers, or a combination thereof.

In the case where the emitting layer emits blue light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.5 to 6.0 eV, and a lowest unoccupied molecular orbital of the dopant material may range from 2.0 to 3.5 eV.

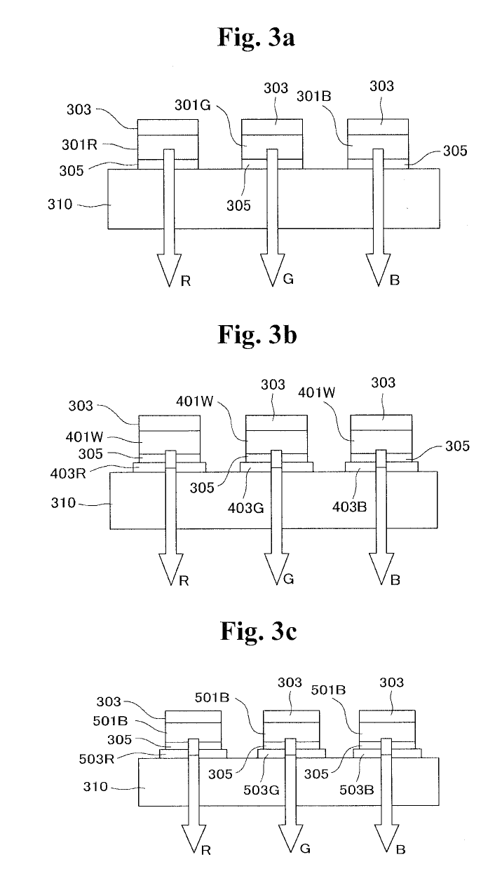

Various color image display methods may be implemented in an organic light emitting device such as described above. These methods will be described below with reference to FIGS. 3A to 3C.

FIGS. 3A to 3C illustrate various implementations of a color image display method in an organic light emitting device according to an exemplary embodiment of the present invention.

First, FIG. 3A illustrates a color image display method in an organic light emitting device separately including a red organic emitting layer 301R, a green organic emitting layer 301G and a blue organic emitting layer 301B which emit red, green and blue light, respectively.

The red, green and blue light produced by the red, green and blue organic emitting layers 301R, 301G and 301B is mixed to display a color image.

It may be understood in FIG. 3A that the red, green and blue organic emitting layers 301R, 301G and 301B each include an electron transfer layer, an emitting layer, a hole transfer layer, and the like. In FIG. 3A, a reference numeral 303 indicates a cathode electrode, 305 an anode electrode, and 310 a substrate. It is possible to variously change a disposition and a configuration of the cathode electrode, the anode electrode and the substrate.

FIG. 3B illustrates a color image display method in an organic light emitting device including a white organic emitting layer 401W, a red color filter 403R, a green color filter 403G and a blue color filter 403B. And an organic light emitting device may further include a white color filter. So the organic light emitting device may realization various colors by manner of R/G/B or R/G/B/W

As illustrated in FIG. 3B, the red color filter 403R, the green color filter 403G and the blue color filter 403B each transmit white light produced by the white organic emitting layer 401W to produce red light, green light and blue light. The red, green and blue light is mixed to display a color image.

It may be understood in FIG. 3B that the white organic emitting layer 401W includes an electron transfer layer, an emitting layer, a hole transfer layer, and the like.

FIG. 3C illustrates a color image display method in an organic light emitting device including a blue organic emitting layer 501B, a red color change medium 503R and a green color change medium 503G.

As illustrated in FIG. 3C, the red color change medium 503R and the green color change medium 503G each transmit blue light produced by the blue organic emitting layer 501B to produce red light, green light and blue light. The red, green and blue light is mixed to display a color image.

It may be understood in FIG. 3C that the blue organic emitting layer 501B includes an electron transfer layer, an emitting layer, a hole transfer layer, and the like.

And a difference between driving voltages, e.g., the power voltages VDD and Vss of the light emitting device may change depending on the size of the light emitting device 100(or 200) and a driving manner. A magnitude of the driving voltage is shown in the following Tables 1 and 2. Table 1 indicates a driving voltage magnitude in case of a digital driving manner, and Table 2 indicates a driving voltage magnitude in case of an analog driving manner.

TABLE 1

| Size (S) | | | |
|---|---|---|---|
| of display panel | VDD-Vss (R) | VDD-Vss (G) | VDD-Vss (B) |
| S < 3 inches | 3.5-10 (V) | 3.5-10 (V) | 3.5-12 (V) |
| 3 inches < S < 20 | 5-15 (V) | 5-15 (V) | 5-20 (V) |
| inches | | | |
| 20 inches < S | 5-20 (V) | 5-20 (V) | 5-25 (V) |

TABLE 2

| Size (S) of display panel | VDD-Vss (R, G, B) |
|---|---|
| S < 3 inches | 4~20 (V) |
| 3 inches < S < 20 inches | 5~25 (V) |
| 20 inches < S | 5~30 (V) |

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device, comprising:
a substrate comprising a thin film transistor;
an insulating film disposed over the thin film transistor;
a first electrode disposed over the insulating film and connected to the thin film transistor;
a light-emitting layer disposed on the first electrode; and
a second electrode disposed on the light-emitting layer, wherein a thickness of the first electrode is substantially 2 to 3.3 times greater than a thickness of the light-emitting layer, and wherein a thickness of the second electrode is substantially 2 to 6.7 times greater than the thickness of the light-emitting layer.

2. The light emitting device of claim 1, wherein:
the first electrode comprises a transparent anode electrode, and
the second electrode comprises a cathode electrode.

3. The light emitting device of claim 1, further comprising:
at least one of a hole injection layer or a hole transfer layer over the first electrode between the first electrode and the light-emitting layer.

4. The light emitting device of claim 1, further comprising:
at least one of an electron transfer layer or an electron injection layer over the light-emitting layer between the light-emitting layer and the second electrode.

5. The light emitting device of claim 3, wherein at least one of the light-emitting layer, the hole injection layer, or the hole transfer layer includes an organic material or an inorganic material.

6. The light emitting device of claim 4, wherein at least one of the electron transfer layer or the electron injection layer includes an organic material or an inorganic material.

7. The light emitting device of claim 5, wherein the hole injection layer includes the organic material and the inorganic material.

8. The light emitting device of claim 6, wherein the electron injection layer includes the organic material and the inorganic material.

9. The light emitting device of claim 7, wherein a highest level of a valence band of the hole injection layer including the inorganic material is lower than a highest level of a valence band of the hole injection layer comprising the organic material without the inorganic material.

10. The light emitting device of claim 8, wherein a lowest level of a conduction band of the electron injection layer including the inorganic material is lower than a lowest level of a conduction band of the electron injection layer including the organic material without the inorganic material.

11. The light emitting device of claim 7, wherein the electron injection layer includes lithium fluoride (LiF) or lithium complex (Liq).

12. A light-emitting device, comprising:
a substrate comprising a thin film transistor;
an insulating film disposed over the thin film transistor;
a first electrode disposed over the insulating film and connected to the thin film transistor;
a light-emitting layer disposed on the first electrode; and
a second electrode disposed on the light-emitting layer, wherein a thickness of the first electrode is substantially 4.2 to 7.7 times greater than a thickness of the light-emitting layer, and wherein a thickness of the second electrode is substantially 0.2 to 0.33 times greater than the thickness of the light-emitting layer.

13. The light emitting device of claim 12, wherein the first electrode comprises any one of a two-layer structure having a reflection electrode/a first transparent electrode or a three-layer structure having a second transparent electrode/a reflection electrode/a first transparent electrode.

14. The light emitting device of claim 12, wherein:
the first electrode comprises an anode electrode, and
the second electrode comprises a cathode electrode.

15. The light emitting device of claim 12, further comprising:
at least one of a hole injection layer or a hole transfer layer over the first electrode between the first electrode and the light-emitting layer.

16. The light emitting device of claim 12, further comprising:
at least one of an electron transfer layer or an electron injection layer over the light-emitting layer between the light-emitting layer and the second electrode.

17. The light emitting device of claim 15, wherein at least one of the light-emitting layer, the hole injection layer, or the hole transfer layer includes an organic material or an inorganic material.

18. The light emitting device of claim 16, wherein at least one of the electron transfer layer and the electron injection layer includes an organic material or an inorganic material.

19. The light emitting device of claim 17, wherein the hole injection layer includes the organic material and the inorganic material.

20. The light emitting device of claim 18, wherein the electron injection layer includes the organic material and the inorganic material.

21. The light emitting device of claim 19, wherein a highest level of a valence band of the hole injection layer including the inorganic material is lower than a highest level of a valence band of the hole injection layer including the organic material without the inorganic material.

22. The light emitting device of claim 20, wherein a lowest level of a conduction band of the electron injection layer including the inorganic material is lower than a lowest level of a conduction band of the electron injection layer including the organic material without the inorganic material.

23. The light emitting device of claim 16, wherein the electron injection layer includes lithium fluoride (LiF) or lithium complex (Liq).

24. A light emitting device, comprising:
a substrate comprising a thin film transistor;
an insulating film disposed over the thin film transistor;
a first electrode disposed over the thin film transistor and connected to the thin film transistor;
a light-emitting layer disposed on the first electrode; and
a second electrode disposed on the light-emitting layer, wherein a thickness of the first electrode is substantially 2 to 3.3 times greater than a thickness of the light-emitting layer, and wherein a thickness of the second electrode is substantially 2 to 6.7 times greater than the thickness of the light-emitting layer,
wherein a highest level of a valence band of a hole injection layer including an inorganic material between the first electrode and the light-emitting layer is lower than a highest level of a valence band of the hole injection layer including a organic material without the inorganic material, and
wherein a lowest level of a conduction band of a electron injection layer including an inorganic material between the light-emitting later and the second electrode is lower than a lowest level of a conduction band of the electron injection layer including an organic material without the inorganic material.

25. A light-emitting device, comprising:
a substrate comprising a thin film transistor;
an insulating film disposed over the thin film transistor;
a first electrode disposed over the thin film transistor and connected to the thin film transistor;
a light-emitting layer disposed on the first electrode; and
a second electrode disposed on the light-emitting layer, wherein a thickness of the first electrode is substantially 4.2 to 7.7 times greater than a thickness of the light-emitting layer, and wherein a thickness of the second electrode is substantially 0.2 to 0.33 times greater than the thickness of the light-emitting layer,
wherein a highest level of a valence band of a hole injection layer including an inorganic material between the first electrode and the light-emitting layer is lower than a highest level of a valence band of the hole injection layer including a organic material without the inorganic material, and
wherein a lowest level of a conduction band of a electron injection layer including an inorganic material between the light-emitting later and the second electrode is lower than a lowest level of a conduction band of the electron injection layer including an organic material without the inorganic material.
